(19) United States
(12) Patent Application Publication
(10) Pub. No.: US 2019/0067538 A1
(43) Pub. Date: Feb. 28, 2019

(54) LIGHT-EMITTING PACKAGE AND LIGHT-EMITTING MODULE INCLUDING THE SAME

(71) Applicant: SAMSUNG ELECTRONICS CO., LTD., SUWON-SI (KR)

(72) Inventors: Jung-wook LEE, Suwon-si (KR); Geun-woo KO, Yongin-si (KR); Pun-jae CHOI, Yongin-si (KR); Jae-ho Han, Hwaseong-si (KR)

(21) Appl. No.: 15/925,037

(22) Filed: Mar. 19, 2018

(30) Foreign Application Priority Data
Aug. 24, 2017 (KR) 10-2017-0107404

(51) Int. Cl. H01L 33/60; H01L 33/62; H01L 33/48; H01L 33/36; H01L 33/50

(52) U.S. Cl. CPC H01L 33/60; H01L 33/62; H01L 33/50; H01L 33/36; H01L 33/486

(57) ABSTRACT

A light-emitting package includes a light-emitting structure having a first surface and a second surface opposite to the first surface. The light-emitting package further includes an electrode layer disposed on the first surface and an insulating layer disposed on the light-emitting structure and the electrode layer. The light-emitting package additionally includes an interconnection conductive layer penetrating the insulating layer and connected to the electrode layer and a reflective layer disposed between the insulating layer and the interconnection conductive layer. The reflective layer reflects light generated from the light-emitting structure in a direction toward the second surface.

### CROSS-REFERENCE TO RELATED APPLICATION

This application claims priority under 35 U.S.C. § 119 to Korean Patent Application No. 10-2017-0107404, filed on Aug. 24, 2017, in the Korean Intellectual Property Office, the disclosure of which is incorporated by reference herein in its entirety.

### TECHNICAL FIELD

The present inventive concept relates to a semiconductor light-emitting device, a light-emitting package, and a light-emitting module.

### DISCUSSION OF THE RELATED ART

Light-emitting diodes (LEDs), which are a type of semiconductor light-emitting devices, have features, such as low power consumption and high luminance. LEDs are used, for example, in backlights, and large displays, and may be used for purposes such as illumination and signaling. As the market for LEDs expands, so does the application range for LEDs.

### SUMMARY

According to an exemplary embodiment of the present inventive concept, a light-emitting package includes a light-emitting structure having a first surface and a second surface opposite to the first surface. The light-emitting package further includes an electrode layer disposed on the first surface and an insulating layer disposed on the light-emitting structure and the electrode layer. The light-emitting package additionally includes an interconnection conductive layer penetrating the insulating layer and connected to the electrode layer and a reflective layer disposed between the insulating layer and the interconnection conductive layer. The reflective layer reflects light generated from the light-emitting structure in a direction toward the second surface.

According to an exemplary embodiment of the present inventive concept, a light-emitting package includes a first region in which a light-emitting structure having a first surface and a second surface opposite to each other is located and a second region adjacent to the first region. The light-emitting package further includes an insulating layer covering the first surface and a side surface of the light-emitting structure and extending from the first region to the second region, an interconnection conductive layer overlapping the insulating layer and extending from the first region to the second region, and a reflective layer disposed between the insulating layer and the interconnection conductive layer.

According to an exemplary embodiment of the present inventive concept, a light-emitting module including a module substrate and a light-emitting package mounted on the module substrate. The light-emitting package includes a light-emitting structure having a first surface and a second surface opposite to the first surface, the light emitting structure including a first semiconductor layer, an active layer, and a second semiconductor layer. The light-emitting package further includes an electrode layer including a first electrode contacting the first semiconductor layer and a second electrode contacting the second semiconductor layer. The light-emitting package further includes an insulating layer covering the first surface and a side surface of the light-emitting structure, a reflective layer overlapping the insulating layer, an adhesive layer disposed between the insulating layer and the reflective layer, and an interconnection conductive layer spaced apart from the insulating layer, and having a first interconnection conductive layer and a second interconnection conductive layer respectively connected to the first electrode and the second electrode.

### BRIEF DESCRIPTION OF THE DRAWINGS

The above and other features of the present inventive concept will be more clearly understood by describing in detail exemplary embodiments thereof with reference to the accompanying drawings in which:

FIG. 1 is a cross-sectional view of a portion of a semiconductor light-emitting device according to an exemplary embodiment of the present inventive concept;

FIG. 2 is a cross-sectional view of a portion of a semiconductor light-emitting device according to an exemplary embodiment of the present inventive concept;

FIGS. 3A, 3B, 3C, 3D, 3E, 3F, 3G, 3H, 3I, 3J and 3K are cross-sectional views illustrating a method of manufacturing the semiconductor light-emitting device shown in FIG. 1 according to an exemplary embodiment of present the inventive concept;

FIG. 4 is a cross-sectional view of a light-emitting package according to an exemplary embodiment of the present inventive concept;

FIG. 5 is an enlarged view of a region V of FIG. 4 according to an exemplary embodiment of the present inventive concept;

FIG. 6 is a graph showing a luminance of the light-emitting package shown in FIG. 4 according to an exemplary embodiment of the present inventive concept;

FIG. 7 is a graph showing a luminance of the light-emitting package shown in FIG. 4 according to an exemplary embodiment of the present inventive concept;

FIG. 8 is a cross-sectional view of a portion of a light-emitting package according to an exemplary embodiment of the present inventive concept;

FIG. 9 is a graph showing a luminance of the light-emitting package shown in FIG. 8 according to an exemplary embodiment of the present inventive concept;

FIG. 10 is a cross-sectional view of a light-emitting module according to an exemplary embodiment of the present inventive concept;

FIG. 11 is a schematic plan view illustrating a dimming system including a semiconductor light-emitting device and/or a light-emitting package, according to an exemplary embodiment of the present inventive concept; and

FIG. 12 is a block diagram of a display apparatus including a semiconductor light-emitting device and/or a light-emitting package, according to an exemplary embodiment of the present inventive concept.

### DETAILED DESCRIPTION OF THE EMBODIMENTS

Exemplary embodiments of the present inventive concept will be described more fully hereinafter in detail with reference to the accompanying drawings.

FIG. 1 is a cross-sectional view of a portion of a semiconductor light-emitting device 100 according to an exemplary embodiment of the present inventive concept.

Referring to FIG. 1, the semiconductor light-emitting device 100 may include a light-emitting structure 110, an insulating layer 120, an electrode layer 130, an interconnection conductive layer 160, an adhesive layer 140, and a reflective layer 150.

The light-emitting structure 110 may have a first surface 110a and a second surface 110b opposite to each other, and may include a first semiconductor layer 111, an active layer 113, and a second semiconductor layer 115 sequentially stacked in a direction from the second surface 110b to the first surface 110a. In an exemplary embodiment of the present inventive concept, the second surface 110b may be a light-emitting surface where light generated in the light-emitting structure 110 is emitted.

The first semiconductor layer 111, the active layer 113, and the second semiconductor layer 115 may each include a gallium nitride-based compound semiconductor which is represented as InₓAl_{y}Ga_{(1-x-y)}N(0≤x≤1, 0≤y≤1, 0≤x+≤1).

In an exemplary embodiment of the present inventive concept, the first semiconductor layer 111 may include an n-type GaN layer for providing electrons to the active layer 113 according to a power supply. The n-type GaN layer may include n-type impurities including Group IV elements. The n-type impurities may include Si, Ge, Sn, etc.

In an exemplary embodiment of the present inventive concept, the second semiconductor layer 115 may include a p-type GaN layer for providing holes to the active layer 113 according to a power supply. The p-type GaN layer may include p-type impurities including Group II elements. In an exemplary embodiment of the present inventive concept, the p-type impurities may include Mg, Zn, Be, etc.

The active layer 113 may emit light having predetermined energy due to recombination of electrons and holes releasing energy in the form of photons. The active layer 113 may have a structure in which a quantum well layer and a quantum barrier layer are alternately stacked at least once. The quantum well layer may have a single quantum well structure or a multi-quantum well structure. In an exemplary embodiment of the present inventive concept, the active layer 113 may include u-AlGaN. In an exemplary embodiment of the present inventive concept, the active layer 113 may have a multi-quantum well structure such as GaN/AlGaN, InAlGaN/InAlGaN, or InGaN/AlGaN. To increase emission efficiency of the active layer 113, a depth of a quantum well, the number of stacks of the quantum well layer and the quantum barrier layer, thicknesses of the quantum well layer and the quantum barrier layer, etc. in the active layer 113 may be changed.

The electrode layer 130 may be disposed on the first surface 110a of the light-emitting structure 110, and may include a first electrode 131 disposed on the first semiconductor layer 111 and a second electrode 136 disposed on the second semiconductor layer 115.

The first electrode 131 and the second electrode 136 may each include a single metal film selected from, for example, Ni, Al, Au, Ti, Cr, Ag, Pd, Cu, Pt, Sn, W, Rh, Ir, Ru, Mg, and Zn, or a multilayer film or alloy film including a combination thereof. In an exemplary embodiment of the present inventive concept, the first electrode 131 and the second electrode 136 may each have a stack structure of Al/Cr/Ti/Pt.

The second electrode 136 may directly contact the second semiconductor layer 115. For example, the second electrode 136 may be disposed directly on the second semiconductor layer 115. However, the present inventive concept is not limited thereto. In an exemplary embodiment of the present inventive concept, another semiconductor layer may be disposed between the second semiconductor layer 115 and the second electrode 136.

The insulating layer 120 may be disposed on the light-emitting structure 110, and may cover a portion of a surface of the light-emitting structure 110 and a portion of a surface of the electrode layer 130. For example, the insulating layer 120 may be disposed on the first surface 110a of the light emitting structure 110. The insulating layer 120 may include a first insulating layer 121 and a second insulating layer 123.

The first insulating layer 121 may be disposed on the surface of the light-emitting structure 110 and may not cover the first electrode 131 and the second electrode 136. For example, the first insulating layer 121 may be disposed on the same layer as the first electrode 131 and the second electrode 136. The second insulating layer 123 may be disposed on the first insulating layer 121, the first electrode 131, and the second electrode 136. The second insulating layer 123 may include a first hole 123H1 partially exposing the first electrode 131 and a second hole 123H2 partially exposing the second electrode 136.

The first insulating layer 121 and the second insulating layer 123 may each include, but are not limited to, a silicon oxide film, a silicon nitride film, an insulating polymer, or a combination thereof.

The interconnection conductive layer 160 may be disposed on the insulating layer 120 and the electrode layer 130. As an example, the reflective layer 150 and the adhesive layer 140 may be disposed between the interconnection conductive layer 160 and the insulating layer 120. The interconnection conductive layer 160 may include a first interconnection conductive layer 161 connected to the first electrode 131 and a second interconnection conductive layer 163 connected to the second electrode 136. The first interconnection conductive layer 161 may be connected to the first electrode 131 via the first hole 123H1 formed in the second insulating layer 123, the second interconnection conductive layer 163 may be connected to the second electrode 136 via the second hole 123H2 formed in the second insulating layer 123, and the first interconnection conductive layer 161 and the second interconnection conductive layer 163 may be insulated from each other. For example, the first interconnection conductive layer 161 and the second interconnection conductive layer 163 may be separated from each other by a gap or an insulating layer disposed therebetween.

The first interconnection conductive layer 161 and the second interconnection conductive layer 163 may each include a multiple metal layer. For example, the first interconnection conductive layer 161 and the second interconnection conductive layer 163 may each have a structure in which a metal reflective film, a metal barrier film, and a metal wiring film are sequentially stacked. The metal reflective film may include Al, Ag, or a combination thereof. The metal barrier film may include Cr, Ti, or a combination thereof. The metal wiring film may include Cu, Cr, or a combination thereof. In an exemplary embodiment of the present inventive concept, the first interconnection conductive layer 161 and the second interconnection conductive layer 163 may each have a stack structure of Al/Cr/Ti/Cr/Ti/Cu/Cr or a stack structure of Ag/Cr/Ti/Cr/Ti/Cu/Cr. However, the present inventive concept is not limited thereto, and various modifications and changes may be made thereto.

The reflective layer 150 may be disposed between the insulating layer 120 and the interconnection conductive layer 160 and may reflect light generated in the light-emitting structure 110. The reflective layer 150 may cover at least a portion of the first surface 110a and reflect light emitted from the first surface 110a to the second surface 110b, which is a light-emitting surface. At a portion where the reflective layer 150 is formed, light emitted from the first surface 110a of the light emitting structure 110 may be reflected by the reflective layer 150 before the light reaches the interconnection conductive layer 160, and thus, degradation of light extraction efficiency due to absorption of light by the interconnection conductive layer 160 may be prevented.

The reflective layer 150 disposed between the second insulating layer 123 and the interconnection conductive layer 160 may extend along a surface of the second insulating layer 123, and may not be formed over a portion of the first electrode 131 exposed via the first hole 123H1 and a portion of the second electrode 136 exposed via the second hole 123H2.

The reflective layer 150 may include, for example, Ag, Al, Ni, Cr, Pd, Cu, Pt, Sn, W, Au, Rh, Ir, Ru, Mg, Zn, or an alloy including at least one thereof. In an exemplary embodiment of the present inventive concept, the reflective layer 150 may include Ag, Al, Pt, a combination thereof, or an alloy including at least one thereof.

The adhesive layer 140 may be disposed between the insulating layer 120 and the reflective layer 150 and may increase adhesion between the insulating layer 120 and the reflective layer 150. The adhesive layer 140 between the reflective layer 150 and the second insulating layer 123 may extend along the surface of the second insulating layer 123.

The adhesive layer 140 may include a highly light-transmissive material to prevent light generated in the light-emitting structure 110 from being absorbed by the adhesive layer 140 before reaching the reflective layer 150. The adhesive layer 140 may be a transparent conductive oxide (TCO). For example, the adhesive layer 140 may include an indium tin oxide (ITO), a zinc oxide (ZnO), an indium zinc oxide (IZO), an indium zinc tin oxide (IZTO), an indium aluminum zinc oxide (IAZO), an indium gallium zinc oxide (IGZO), an indium gallium tin oxide (IGTO), an aluminum zinc oxide (AZO), an antimony tin oxide (ATO), a gallium zinc oxide (GZO), or a combination thereof.

In an exemplary embodiment of the present inventive concept, as the reflective layer 150 is between the insulating layer 120 and the interconnection conductive layer 160, light loss due to absorption of light by the interconnection conductive layer 160 may decrease, and an amount of light emitted through the second surface 110b may increase, thereby increasing light extraction efficiency. Further, in an exemplary embodiment of the present inventive concept, the adhesive layer 140 capable of increasing adhesion between the reflective layer 150 and the insulating layer 120 is disposed between the reflective layer 150 and the insulating layer 120, and accordingly, the reflective layer 150 may be prevented from being exfoliated from the insulating layer 120.

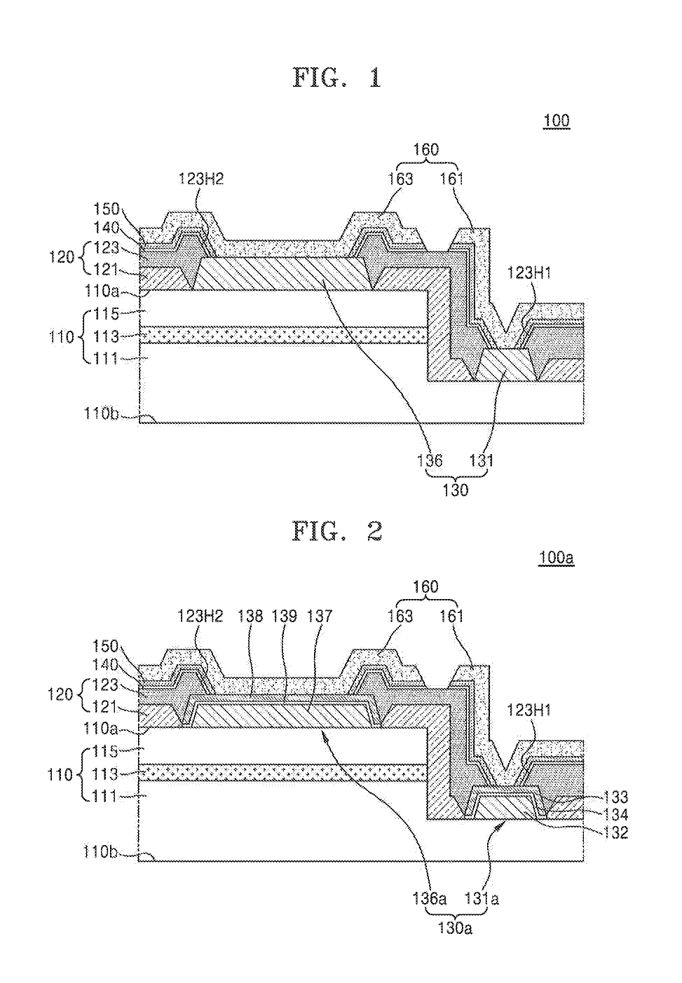

FIG. 2 is a cross-sectional view of a portion of a semiconductor light-emitting device 100a according to an exemplary embodiment of the present inventive concept.

The semiconductor light-emitting device 100a shown in FIG. 2 may have substantially the same configuration as the semiconductor light-emitting device 100 shown in FIG. 1 except an electrode layer 130a. In FIG. 2, elements that are the same as those in FIG. 1 are designated by the same reference numerals, and a repeated description thereof may be omitted.

Referring to FIG. 2, the electrode layer 130a may include a first electrode 131a and a second electrode 136a.

The first electrode 131a may include a first lower electrode structure 132, a first upper electrode structure 133, and a first fixing structure 134.

The first lower electrode structure 132 may be disposed on the first surface 110a of the light-emitting structure 110, and may contact the first semiconductor layer 111. The first lower electrode structure 132 may include a single metal film selected from Ni, Al, Au, Ti, Cr, Ag, Pd, Cu, Pt, Sn, W, Rh, Ir, Ru, Mg, and Zn, or a multilayer film or alloy film including a combination thereof. In an exemplary embodiment of the present inventive concept, the first lower electrode structure 132 may include Ag, Al, a combination thereof, or an alloy including at least one thereof.

The first upper electrode structure 133 may cover at least a portion of the first lower electrode structure 132 and thus may block contact between the first lower electrode structure 132 and the insulating layer 120. In other words, the first upper electrode structure 133 is disposed between the first lower electrode structure 132 and the insulating layer 120. For example, when the first lower electrode structure 132 includes Ag, Ag is thermally and/or chemically unstable, and thus, may react with sulfur in the air to form a silver sulfide or may react with oxygen in the air to form an oxide, thereby causing a leakage current or damaging the first lower electrode structure 132 during a process of manufacturing the semiconductor light-emitting device 100a. However, the first upper electrode structure 133 including a material that is more thermally and/or chemically stable than that of the first lower electrode structure 132 may prevent damage to the first lower electrode structure 132 or an occurrence of a leakage current by covering the first lower electrode structure 132.

In addition, the first upper electrode structure 133 may surround the first lower electrode structure 132, and at least a portion of the first upper electrode structure 133 may face the first surface 110a. The first upper electrode structure 133 may include a metal having relatively high reflectivity and thus may increase an amount of light reflected by the first electrode 131a, thereby increasing light extraction efficiency.

The first upper electrode structure 133 may include a single metal film selected from Ni, Al, Au, Ti, Cr, Ag, Pd, Cu, Pt, Sn, W, Rh, Ir, Ru, Mg, and Zn, or a multilayer film or alloy film including a combination thereof. In an exemplary embodiment of the present inventive concept, the first upper electrode structure 133 may have a stack structure of Ag/Cr/Ti, a stack structure of Ag/Ni/Ti, or a combination thereof.

In an exemplary embodiment of the present inventive concept, a material of the first upper electrode structure 133 may be the same as that of the first lower electrode structure 132. In an exemplary embodiment of the present inventive concept, a material of the first upper electrode structure 133 may be different from that of the first lower electrode structure 132.

The first fixing structure 134 may be disposed between the first lower electrode structure 132 and the first upper electrode structure 133 and between the first upper electrode structure 133 and the first surface 110a of the light-emitting structure 110. The first fixing structure 134 may be disposed between the first lower electrode structure 132 and the first upper electrode structure 133 to increase adhesion between the first lower electrode structure 132 and the first upper electrode structure 133, and may be disposed between the first upper electrode structure 133 and the light-emitting structure 110 to increase adhesion between the first upper electrode structure 133 and the light-emitting structure 110.

The first fixing structure 134 may include a highly light-transmissive material to prevent light from being absorbed by the first fixing structure 134 before reaching the first upper electrode structure 133. For example, the first fixing structure 134 may be a TCO. For example, the first fixing structure 134 may include an ITO, a ZnO, an IZO, an IZTO, an IAZO, an IGZO, an IGTO, an AZO, an ATO, a GZO, or a combination thereof.

The second electrode 136a may include a second lower electrode structure 137, a second upper electrode structure 138, and a second fixing structure 139 disposed on the first surface 110a of the light-emitting structure 110. The second upper electrode structure 138 may be disposed on the second lower electrode structure 137 disposed on the first surface 110a of the light emitting structure 110. The second fixing structure 139 may be disposed between the second upper electrode structure 138 and the second lower electrode structure 137. The second lower electrode structure 137, the second upper electrode structure 138, and the second fixing structure 139 may respectively correspond to the first lower electrode structure 132, the first upper electrode structure 133, and the first fixing structure 134 of the first electrode 131a described above. For example, the second lower electrode structure 137, the second upper electrode structure 138, and the second fixing structure 139 may respectively perform substantially the same functions as the first lower electrode structure 132, the first upper electrode structure 133, and the first fixing structure 134, and may respectively include materials that are substantially the same as those of the first lower electrode structure 132, the first upper electrode structure 133, and the first fixing structure 134.

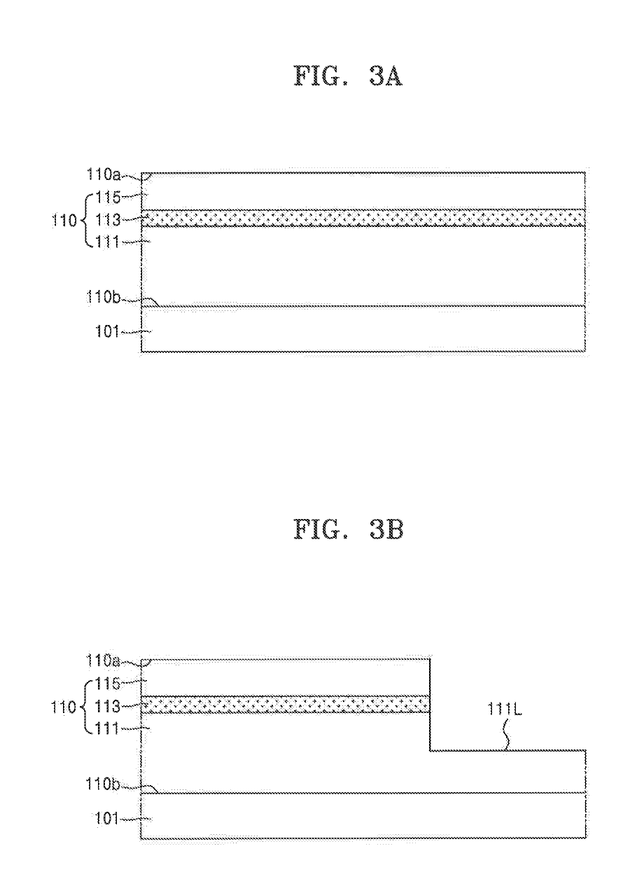

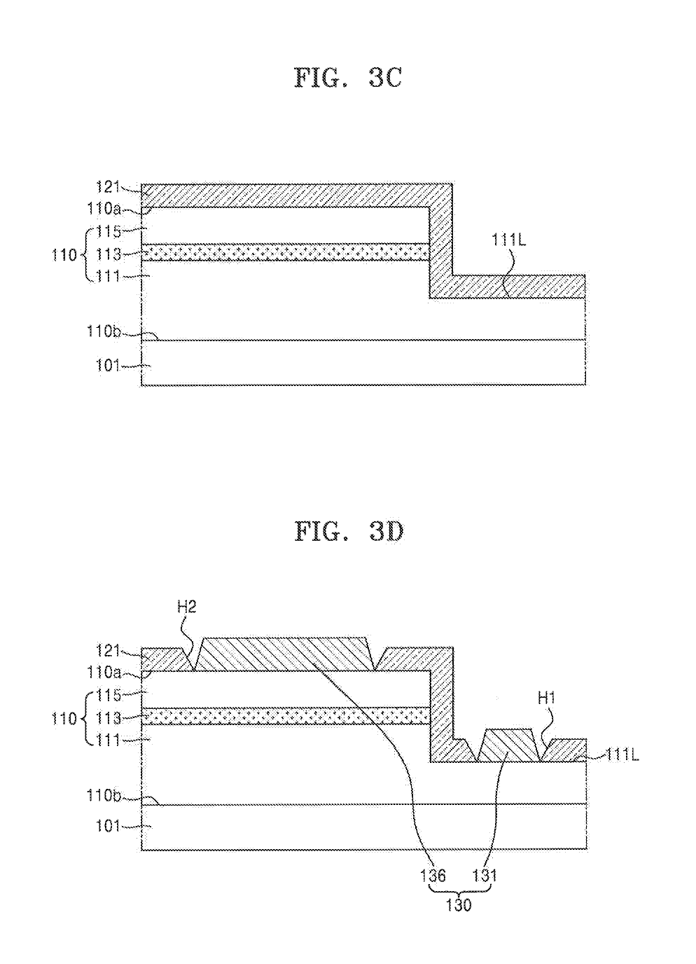

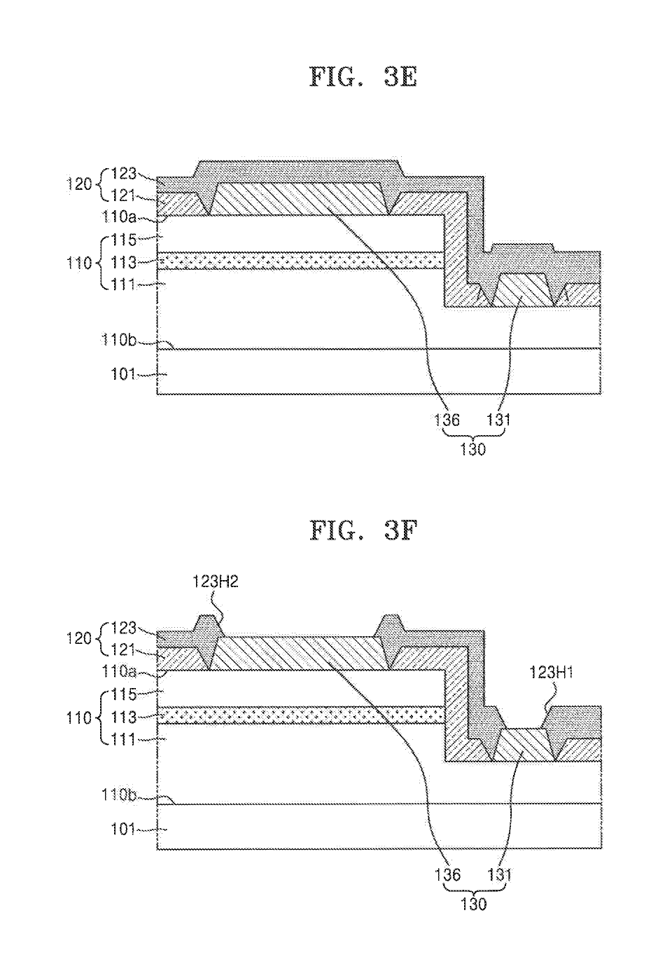

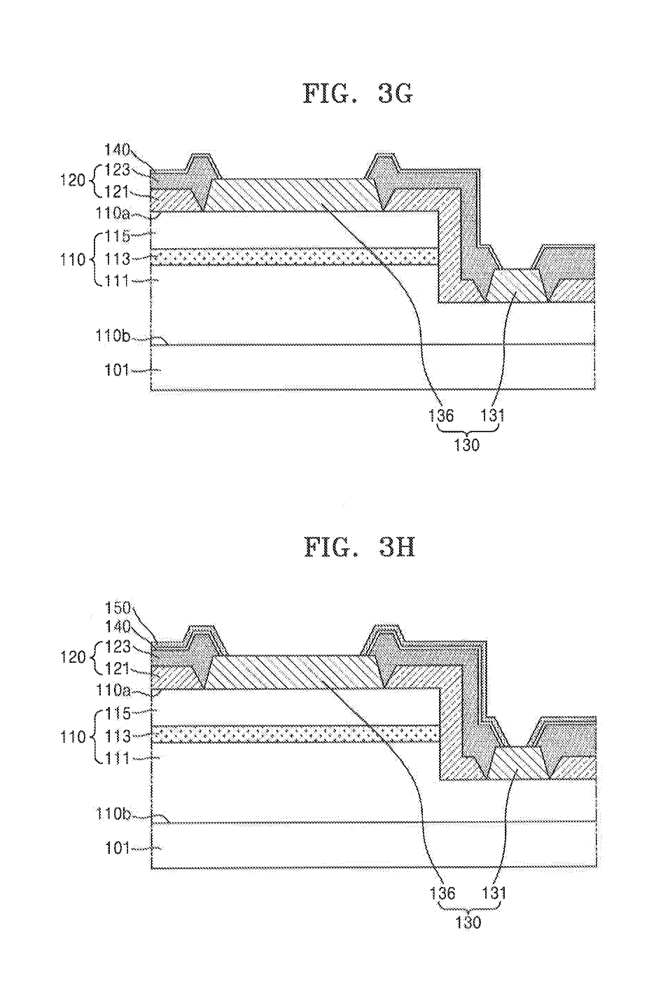

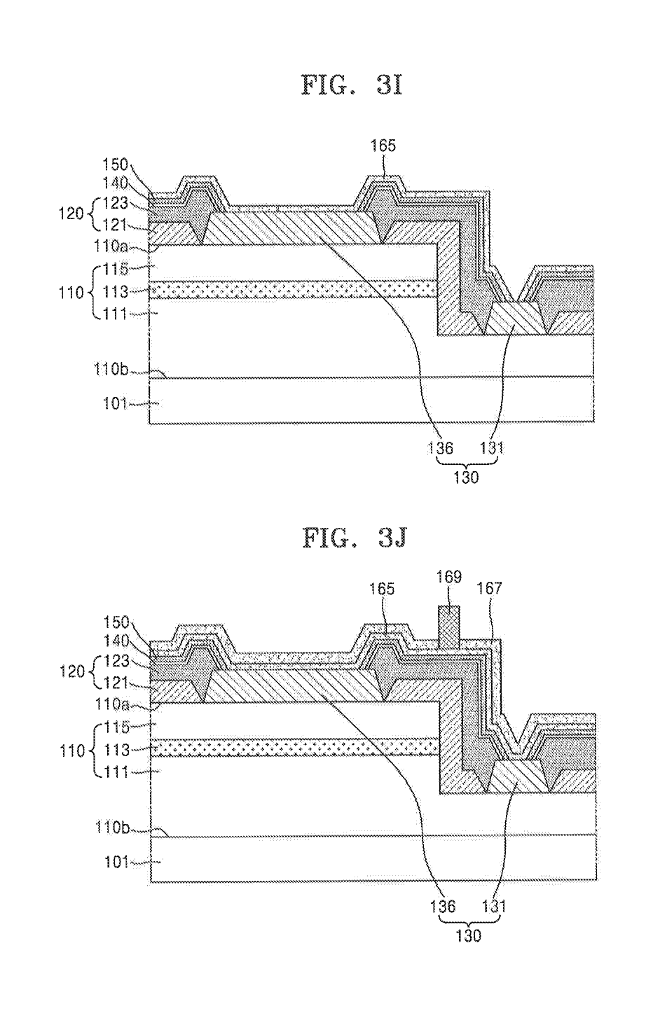

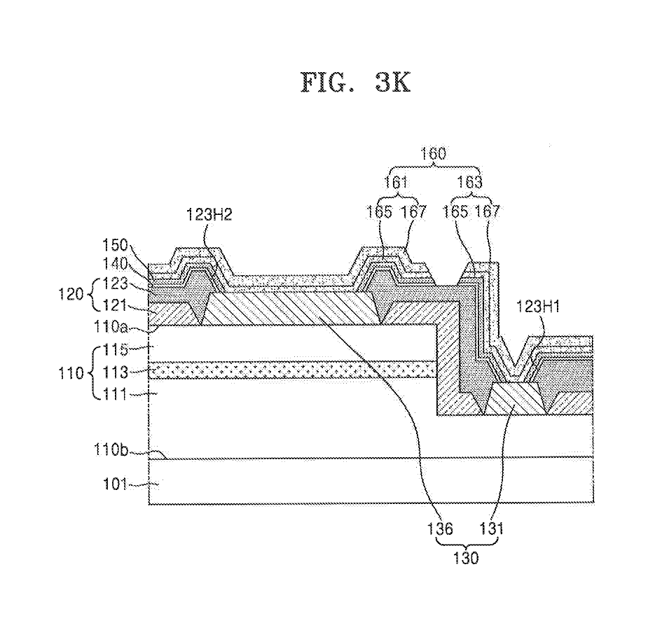

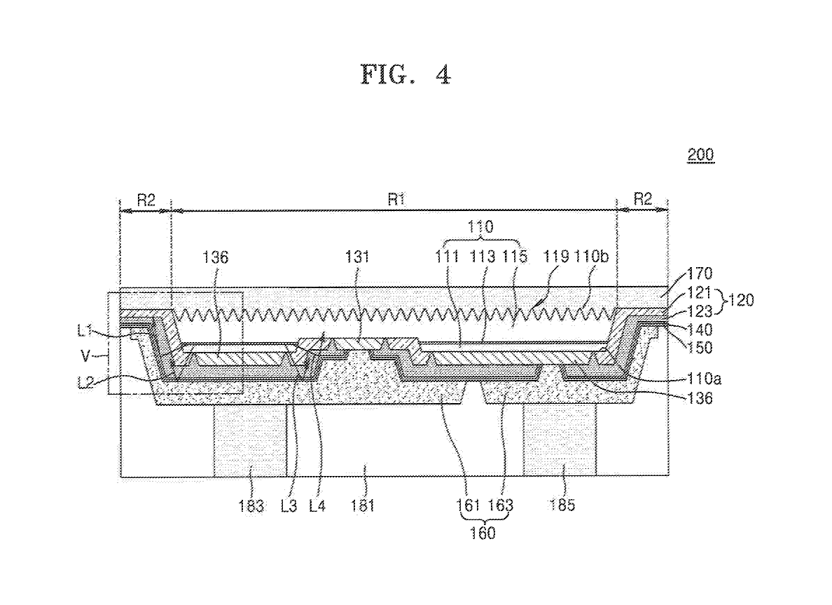

FIGS. 3A, 3B, 3C, 3D, 3E, 3F, 3G, 3H, 3I, 3J and 3K are cross-sectional views illustrating a method of manufacturing the semiconductor light-emitting device 100 shown in FIG. 1 according to an exemplary embodiment of the present inventive concept. In FIGS. 3A to 3K, elements that are the same as those in FIG. 1 are designated by the same reference numerals, and a repeated description thereof may be omitted.

Referring to FIG. 3A, the light-emitting structure 110 having the first semiconductor layer 111, the active layer 113, and the second semiconductor layer 115 is formed on the substrate 101. In an exemplary embodiment of the present inventive concept, the substrate 101 may be a silicon substrate.

In an exemplary embodiment of the present inventive concept, the light-emitting structure 110 may be formed by metal-organic chemical vapor deposition (MOCVD), hydride vapor phase epitaxy (HVPE), or molecular beam epitaxy (MBE) processes.

Referring to FIG. 3B, a low surface portion 111L of the first semiconductor layer 111 is formed by mesa-etching a portion of the light-emitting structure 110 from the second semiconductor layer 115 to a portion of the first semiconductor layer 111. In other words, the light-emitting structure 110 is etched such that the low surface portion 111L of the first semiconductor layer 111 is exposed.

The light-emitting structure 110 may be mesa-etched by reactive ion etching (RIE) processes.

Referring to FIG. 3C, the first insulating layer 121 covering the light-emitting structure 110 and an exposed surface of the low surface portion 111L of the first semiconductor layer 111 is formed.

In an exemplary embodiment of the present inventive concept, the first insulating layer 121 may be formed by plasma-enhanced chemical vapor deposition (PECVD), physical vapor deposition (PVD), or spin coating processes.

Referring to FIG. 3D, a hole H1 exposing the low surface portion 111L of the first semiconductor layer 111 is formed by etching a portion of the first insulating layer 121, and then, the first electrode 131 is formed in the hole H1 to be connected to the first semiconductor layer 111.

In addition, a hole H2 exposing an upper surface of the second semiconductor layer 115 is formed by etching another portion of the first insulating layer 121, and then, the second electrode 136 is formed in the hole H2 to be connected to the second semiconductor layer 115.

In an exemplary embodiment of the present inventive concept, wet etching processes using RIE processes and a buffered oxide etchant (BOE) may be used to form the holes HI and H2 in the first insulating layer 121.

In an exemplary embodiment of the present inventive concept, the first electrode 131 and the second electrode 136 may be formed by directed vapor deposition (DVD) processes using electron beam evaporation.

In the present embodiment, the second electrode 136 may be formed after the first electrode 131 is formed. However, an order in which the first electrode 131 and the second electrode 136 are formed is not limited thereto. For example, the second electrode 136 may be formed before the first electrode 131.

Referring to FIG. 3E, the second insulating layer 123 covering each of the first insulating layer 121, the first electrode 131, and the second electrode 136 is formed.

In an exemplary embodiment of the present inventive concept, the second insulating layer 123 may be formed by the PECVD, PVD, or spin coating processes.

Referring to FIG. 3F, a first hole 123H1 exposing a portion of the first electrode 131 and a second hole 123H2 exposing a portion of the second electrode 136 are formed by etching a portion of the second insulating layer 123.

To form the first hole 123H1 and the second hole 123H2, a mask pattern in which a plurality of holes partially exposing the second insulating layer 123 are formed may be formed on the second insulating layer 123, and then, the second insulating layer 123 may be etched by using the mask pattern as an etching mask. In addition, the second insulating layer 123 may be exposed by removing the mask pattern used as an etching mask. For example, RIE processes may be used to etch the second insulating layer 123.

Referring to FIG. 3G, the adhesive layer 140 is formed on the second insulating layer 123. In an exemplary embodiment of the present inventive concept, to form the adhesive layer 140, a TCO covering the second insulating layer 123 may be formed, and a portion of the TCO may be removed to expose the first electrode 131 and the second electrode 136.

In an exemplary embodiment of the present inventive concept, unlike as illustrated in FIGS. 3G and 3H, a portion of the adhesive layer 140 for exposing the first electrode 131 and the second electrode 136 and a portion of the reflective layer 150 may be removed by using the same mask pattern. In other words, a material film constituting the adhesive layer 140 and a material film constituting the reflective layer 150 are sequentially stacked on the second insulating layer 123, and the mask pattern is formed on the material film constituting the reflective layer 150. Next, by using the mask pattern as an etching mask, a portion of the material film constituting the adhesive layer 140 and a portion of the material film constituting the reflective layer 150 may be removed to expose the first electrode 131 and the second electrode 136.

Referring to FIG. 3H, the reflective layer 150 is formed on the adhesive layer 140. In an exemplary embodiment of the present inventive concept, to form the reflective layer 150, a metal film including a metal having high reflectivity may be formed on the adhesive layer 140, and then, a portion of the metal film may be removed to expose the first electrode 131 and the second electrode 136.

Referring to FIG. 3I, a first sub metal layer 165 covering the reflective layer 150 the first electrode 131, and the second electrode 136 exposed through the second insulating layer 123 is formed.

In an exemplary embodiment of the present inventive concept, the first sub metal layer 165 may have a multilayer structure in which a plurality of metal layers are repeatedly stacked. For example, the first sub metal layer 165 may include a Ag/Ti/Cu metal layer or a Ag/Cr/Cu metal layer. In an exemplary embodiment of the present inventive concept, the first sub metal layer 165 may be formed by sputtering processes.

Referring to FIG. 3J, a second sub metal layer 167 is formed on the first sub metal layer 165. In an exemplary embodiment of the present inventive concept, the second sub metal layer 167 may be formed through plating processes using the first sub metal layer 165 as a seed layer. For example, a mask pattern 169 covering a portion of the first sub metal layer 165 is formed, and then, the second sub metal layer 167 is formed around the mask pattern 169 and on the first sub metal layer 165 by the plating processes using the first sub metal layer 165 as a seed layer. In an exemplary embodiment of the present inventive concept, the second sub metal layer 167 may be formed by immersion plating, electroless plating, electroplating, or a combination thereof.

The second sub metal layer 167 may be integrally formed with the first sub metal layer 165, and may constitute the first interconnection conductive layer 161 connected to the first electrode 131 and the second interconnection conductive layer 163 connected to the second electrode 136.

Referring to FIG. 3K, the mask pattern 169 shown in FIG. 3J is removed. For example, ashing or strip processes may be used to remove the mask pattern 169.

After the mask pattern 169 is removed, a portion of the first sub metal layer 165 is exposed, and that exposed portion may be removed. Next, a portion of the reflective layer 150 under the removed portion of the first sub metal layer 165 and a portion of the adhesive layer 140 may be removed to expose a surface of the second insulating layer 123.

Next, the substrate 101 may be removed, and for example, at least one of grinding processing and etching processing may be performed to remove the substrate 101.

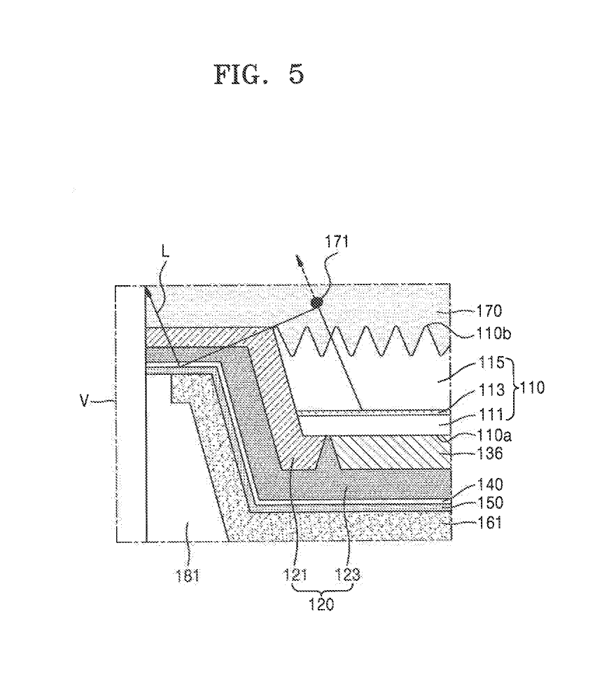

FIG. 4 is a cross-sectional view of a light-emitting package 200 according to an exemplary embodiment of present the inventive concept. FIG. 5 is an enlarged view of a region V of FIG. 4 according to an exemplary embodiment of the present inventive concept.

Referring to FIG. 4, the light-emitting package 200 may include the light-emitting structure 110, the insulating layer 120, the first electrode 131, the second electrode 136, the reflective layer 150, the adhesive layer 140, the interconnection conductive layer 160, a wavelength conversion layer 170, a first pillar 183, a second pillar 185, and a resin layer 181. The light-emitting package 200, which is a chip scale package (CSP), is illustrated in FIG. 4. In FIG. 4, elements that are the same as those in FIGS. 1 to 3 may be designated by the same reference numerals, and a repeated description thereof may be omitted.

Referring to FIG. 4, the light-emitting package 200 may include a first region R1 in which the light-emitting structure 110 is located, and a second region R2 around the first region R1. For example, second region R2 may surround the first region R1.

The insulating layer 120 may be located in the first region R1 and the second region R2. In the first region R1, the insulating layer 120 may extend along a surface of the light-emitting structure 110 to at least partially cover the first surface 110a and a side surface of the light-emitting structure 110. For example, the insulating layer 120 may partially surround the light-emitting structure 110 such that the second surface 110b of the light-emitting structure 110 is exposed. In the second region R2, the insulating layer 120 may extend from the side surface of the light-emitting structure 110 to an area outside of the light-emitting structure 110. For example, the insulating layer 120 in the second region R2 may surround the light-emitting structure 110.

In an exemplary embodiment of the present inventive concept, the wavelength conversion layer 170 may be disposed on the insulating layer 120, and the insulating layer 120 may include a portion within the second region R2 extending parallel to the wavelength conversion layer 170. For example, the insulating layer 120 may include a portion extending parallel to a surface of the wavelength conversion layer 170, for example, a surface of the wavelength conversion layer 170 contacting the insulating layer 120 in the second region R2.

In an exemplary embodiment of the present inventive concept, the insulating layer 120 may extend to an edge of the light-emitting package 200. The insulating layer 120 may be exposed via a side surface of the light-emitting package 200, and a side surface of the insulating layer 120 may partially constitute the side surface of the light-emitting package 200.

The interconnection conductive layer 160 may be located in the first region R1 and the second region R2. In the first region R1, the interconnection conductive layer 160 may be formed on the insulating layer 120 and may be connected to the first electrode 131 and/or the second electrode 136. In the second region R2, the interconnection conductive layer 160 may extend along a surface of the insulating layer 120.

In an exemplary embodiment of the present inventive concept, the interconnection conductive layer 160 may include a portion within the second region R2 extending parallel to the wavelength conversion layer 170. For example, the interconnection conductive layer 160 may include a portion extending parallel to a surface of the wavelength conversion layer 170, for example, a surface of the wavelength conversion layer 170 contacting the insulating layer 120 in the second region R2. In the first region R1 and the second region R2, the interconnection conductive layer 160 may be covered by the resin layer 181.

As the interconnection conductive layer 160 is formed not only in the first region R1, which is a central portion of the light-emitting package 200, but also in the second region R2, which is a peripheral region of the light-emitting package 200, stress applied to the light-emitting package 200 (e.g., stress applied during a process of manufacturing the light-emitting package 200) may be reduced.

The reflective layer 150 may be located over the first region R1 and the second region R2. The reflective layer 150 may extend to the edge of the light-emitting package 200 along the insulating layer 120. For example, the reflective layer 150 may overlap the insulating layer 120.

In an exemplary embodiment of the present inventive concept, the reflective layer 150 may include a portion within the second region R2 extending parallel to the wavelength conversion layer 170. For example, the reflective layer 150 may include a portion extending parallel to a surface of the wavelength conversion layer 170, for example, a surface of the wavelength conversion layer 170 contacting the insulating layer 120 in the second region R2.

In an exemplary embodiment of the present inventive concept, the reflective layer 150 may extend to the edge of the light-emitting package 200. The reflective layer 150 may be exposed via the side surface of the light-emitting package 200, and a side surface of the reflective layer 150 may partially constitute the side surface of the light-emitting package 200.

As the reflective layer 150 is disposed between the interconnection conductive layer 160 and the insulating layer 120, light loss over the first region R1 and the second region R2 may decrease. For example, as shown in FIG. 4, the reflective layer 150 may reflect second light L2, third light L3, and fourth light L4 emitted through the first surface 110a around the first electrode 131 and the second electrode 136, and thus, may redirect the second light L2, the third light L3, and the fourth light L4 to be emitted through the second surface 110b or the wavelength conversion layer 170. In addition, the reflective layer 150 may reflect first light L1 emitted through the side surface of the light-emitting structure 110 to be emitted through the second surface 110b or the wavelength conversion layer 170.

In an exemplary embodiment of the present inventive concept, a side surface of the reflective layer 150 may be at a predetermined angle with respect to the first surface 110a of the light emitting structure 110. Accordingly, the first light L1 emitted through the side surface of the light-emitting structure 110 may be reflected to be emitted through the second surface 110b or the wavelength conversion layer 170. However, the present inventive concept is not limited thereto.

In addition, as shown in FIG. 5, the reflective layer 150 may be at an edge portion of the light-emitting package 200. Thus, light may be prevented from being absorbed by the interconnection conductive layer 160 and/or the resin layer 181, and light travelling to the side surface or a lower portion of the light-emitting package 200 may be reflected so that the light may be emitted to an upper portion of the light-emitting package 200. For example, light L emitted through the second surface 110b of the light-emitting structure 110 may be reflected or scattered by phosphor particles 171 to travel toward a side portion or the lower portion of the light-emitting package 200. In the second region R2, the reflective layer 150 extends to a region outside of the light-emitting structure 110, and accordingly, the light L may be reflected by the reflective layer 150 and may be emitted to the upper portion of the light-emitting package 200 through the wavelength conversion layer 170.

The wavelength conversion layer 170 may cover the second surface 110b of the light-emitting structure 110, and may cover a surface of the insulating layer 120 within the second region R2. The wavelength conversion layer 170 may convert a wavelength of light emitted from the light-emitting structure 110 of the light-emitting package 200 into another wavelength. In an exemplary embodiment of the present inventive concept, the wavelength conversion layer 170 may include a resin including phosphor or quantum dots. In an exemplary embodiment of the present inventive concept, the wavelength conversion layer 170 may convert a wavelength of light so that final light emitted from the light-emitting package 200 may be, for example, white light.

In an exemplary embodiment of the present inventive concept, the light-emitting structure 110 may have an uneven pattern 119 in the second surface 110b contacting the wavelength conversion layer 170. As the uneven pattern 119 is formed in the second surface 110b, which is a light-emitting surface, light extraction efficiency due to diffused reflection of light may increase, thereby increasing light extraction efficiency of the light-emitting package 200.

The first pillar 183 and the second pillar 185 may be respectively disposed on the first interconnection conductive layer 161 and the second interconnection conductive layer 163. The first pillar 183 may be electrically connected to the first electrode 131 via the first interconnection conductive layer 161, and the second pillar 185 may be electrically connected to the second electrode 136 via the second interconnection conductive layer 163. The first pillar 183 and the second pillar 185 may be formed by plating.

The resin layer 181 may cover the interconnection conductive layer 160, the first pillar 183, and the second pillar 185. In an exemplary embodiment of the present inventive concept, the resin layer 181 may include an epoxy resin, a silicone resin, a fluororesin, or a combination thereof.

In an exemplary embodiment of the present inventive concept, the resin layer 181 may constitute the side surface of the light-emitting package 200, along with the insulating layer 120, the wavelength conversion layer 170, the reflective layer 150, and the adhesive layer 140. For example, the resin layer 181, the insulating layer 120, the wavelength conversion layer 170, the reflective layer 150, and the adhesive layer 140 may be coplanar.

The light-emitting package 200 according to an exemplary embodiment of the present inventive concept, which is a CSP, may be a package having substantially the same size as an ordinary light-emitting device chip, and may decrease light loss through the reflective layer 150, thereby obtaining a large amount of light per unit area. Further, the light-emitting package 200 enables mass production because every process is performed at a wafer level.

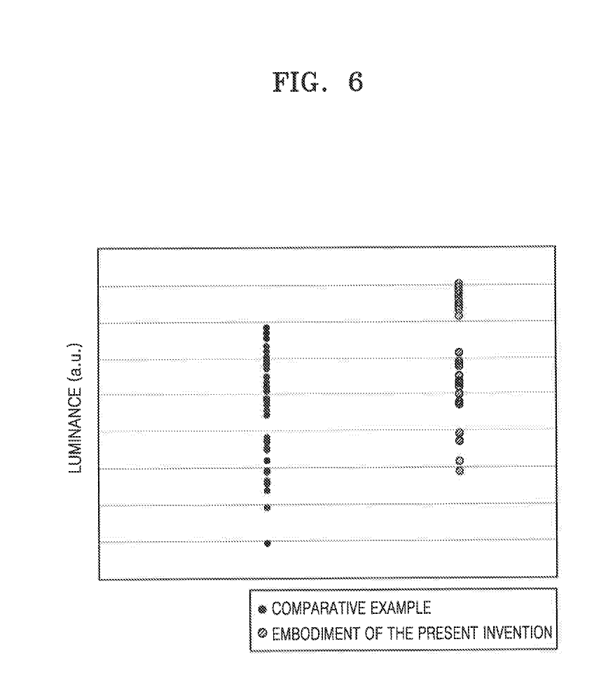

FIG. 6 is a graph showing a luminance of the light-emitting package 200 shown in FIG. 4 according to an exemplary embodiment of the present inventive concept. FIG. 6 shows each of a luminance of the light-emitting package 200 according to the present embodiment shown in FIG. 4 and a luminance of a light-emitting package according to a comparative example in which the reflective layer 150 and the adhesive layer 140 are omitted.

Referring to FIGS. 4 and 6, as described above, the light-emitting package 200 according to the present embodiment includes the reflective layer 150, and accordingly, light loss due to the interconnection conductive layer 160 may decrease. In addition, in the light-emitting package 200 according to the present embodiment, the reflective layer 150 extends to an edge portion of the light-emitting package 200, and accordingly, light loss due to the interconnection conductive layer 160 and/or the resin layer 181 may decrease at the edge portion of the light-emitting package 200. In other words, as shown in FIG. 6, it may be found that, as light loss decreases, an amount of light which is emitted through the second surface 110b and the wavelength conversion layer 170 increases and light extraction efficiency of the light-emitting package 200 increases.

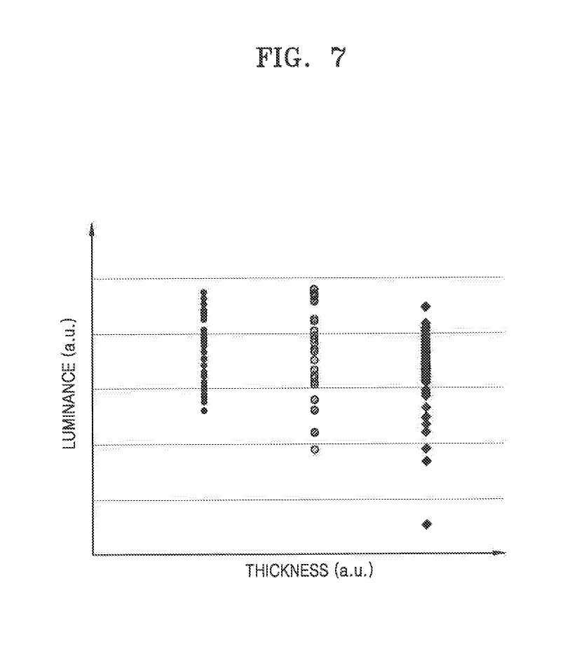

FIG. 7 is a graph showing a luminance of the light-emitting package 200 shown in FIG. 4 according to an exemplary embodiment of the present inventive concept. In FIG. 7, the graph shows a change in luminance according to a thickness of the adhesive layer 140.

Referring to FIGS. 4 and 7, it may be found that a luminance of the light-emitting package 200 changes according to a thickness of the adhesive layer 140 and that the luminance increases as the thickness of the adhesive layer 140 decreases. In other words, light loss due to the adhesive layer 140 may gradually increase as the thickness of the adhesive layer 140 increases, and as a result, light extraction efficiency may decrease. Accordingly, a thickness of the adhesive layer 140 may prevent exfoliation of the reflective layer 150, and be capable of minimizing light loss. Thus, the light-emitting package 200 may have an increased light extraction efficiency and reliability.

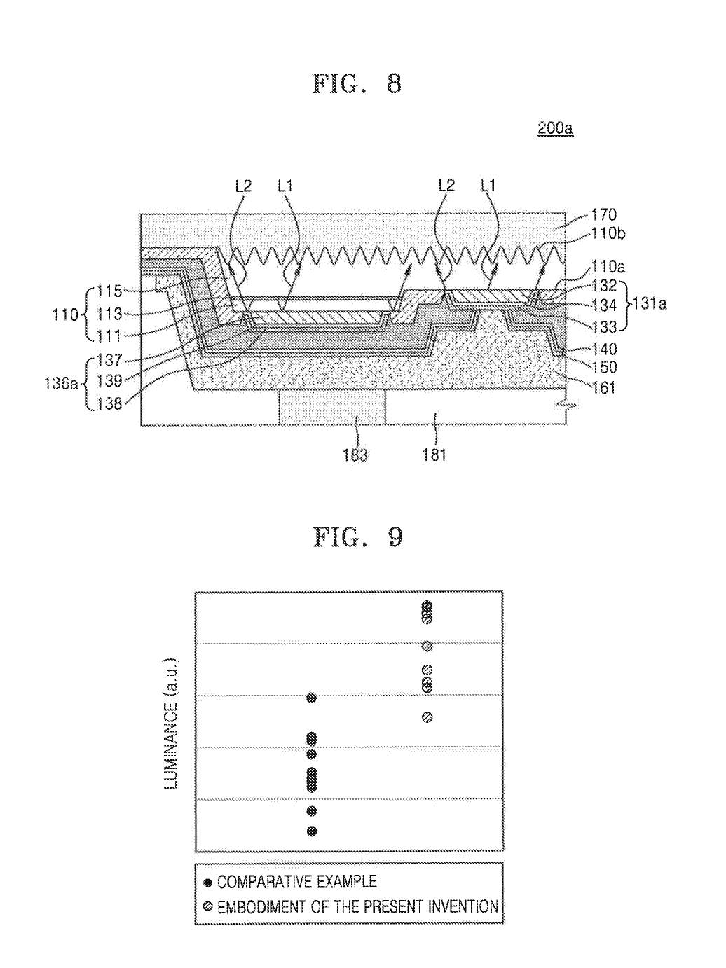

FIG. 8 is a cross-sectional view of a portion of a light-emitting package 200a according to an exemplary embodiment of the present inventive concept.

The light-emitting package 200a shown in FIG. 8 may have substantially the same configuration as the light-emitting package 200 shown in FIG. 5 except the first electrode 131a and the second electrode 136a, and the first electrode 131a and the second electrode 136a of FIG. 8 may have substantially the same structure as the first electrode 131a and the second electrode 136a of the semiconductor light-emitting device 100a shown in FIG. 2. In FIG. 8, elements that are the same as those in previous figures may be designated by the same reference numerals, and a repeated description thereof may be omitted.

As shown in FIG. 8, since the first upper electrode structure 133 of the first electrode 131a may include a metal having relatively high reflectivity, light L1 and L2 travelling toward the first electrode 131a may be reflected by the first lower electrode structure 132 and the first upper electrode structure 133 of the first electrode 131a toward the wavelength conversion layer 170. In addition, light L1 and L2 travelling toward the second electrode 136a may be reflected by the second lower electrode structure 137 and the second upper electrode structure 138 of the second electrode 136a toward the wavelength conversion layer 170.

FIG. 9 is a graph showing a luminance of the light-emitting package 200a shown in FIG. 8 according to an exemplary embodiment of the present inventive concept. FIG. 9 shows each of a luminance of the light-emitting package 200a according to the present embodiment shown in FIG. 8 and a luminance of a light-emitting package according to a comparative example in which a portion corresponding to the first upper electrode structure 133 and the second upper electrode structure 138 includes a metal having low reflectivity.

Referring to FIGS. 8 and 9, it may be found that the light-emitting package 200a according to the present embodiment has an increased luminance. For example, reflecting areas of the first electrode 131a and the second electrode 136a may be respectively expanded by the first upper electrode structure 133 of the first electrode 131a and the second upper electrode structure 138 of the second electrode 136a. In addition, an amount of light which is emitted through the second surface 110b and the wavelength conversion layer 170 may increase, thereby increasing light extraction efficiency of the light-emitting package 200a.

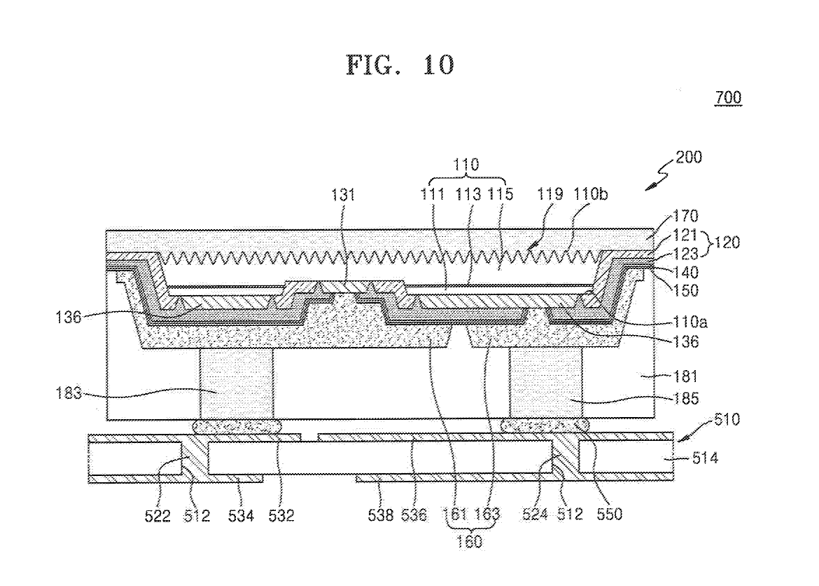

FIG. 10 is a cross-sectional view of a light-emitting module 700 according to an exemplary embodiment of the present inventive concept.

Referring to FIG. 10, the light-emitting module 700 may include a module substrate 510 and the light-emitting package 200 mounted on the module substrate 510. The light-emitting package 200 is electrically connected to the module substrate 510 via a connection member 550. For example, the light-emitting module 700 may be used to in a large display, a light-emitting diode television (LED TV), RGB white illumination, emotional illumination, etc. The light-emitting package 200 shown in FIG. 10 may be substantially the same as the light-emitting package 200 described above with reference to FIG. 4, and a repeated description thereof may be omitted.

The module substrate 510 includes a body portion 514 including a plurality of through holes 512, and a plurality of through electrodes 522 and 524 formed in the plurality of through holes 512, a plurality of wiring layers, for example, first to fourth wiring layers 532, 534, 536, and 538, formed on two surfaces of the body portion 514. The first to fourth wiring layers 532, 534, 536, and 538 include the first wiring layer 532 and the second wiring layer 534 respectively connected to two end portions of the through electrode 522 at the two surfaces of the body portion 514, and the third wiring layer 536 and the fourth wiring layer 538 respectively connected to two end portions of the through electrode 524 at the two surfaces of the body portion 514. The first wiring layer 532 and the third wiring layer 536 may be apart from each other at one surface of the body portion 514, and the second wiring layer 534 and the fourth wiring layer 538 may be apart from each other at the other surface of the body portion 514.

The body portion 514 may include a circuit substrate such as a printed circuit board (PCB), a metal core PCB (MCPCB), a metal PCB (MPCB), or a flexible PCB (FPCB), or a ceramic substrate such as AlN or Al₂O₃.

The plurality of through electrodes 522 and 524 and the first to fourth wiring layers 532, 534, 536, and 538 may each include, for example, Cu, Au, Ag, Ni, W, Cr, or a combination thereof.

The light-emitting package 200 may be mounted on the module substrate 510 by a flip chip method. In other words, the light-emitting package 200 may be disposed above the module substrate 510 such that a surface of the light-emitting package 200 where the first pillar 183 and the second pillar 185 are exposed faces a surface of the module substrate 510. In addition, the first pillar 183 may be connected to the first wiring layer 532 by the connection member 550, and the second pillar 185 may be connected to the third wiring layer 536 by the connection member 550.

Although FIG. 10 shows an example in which the light-emitting package 200 shown in FIG. 4 is mounted on the module substrate 510, the light-emitting package 200a shown in FIG. 8 may be mounted on the module substrate 510 by using a method similar to that described above with reference to FIG. 10.

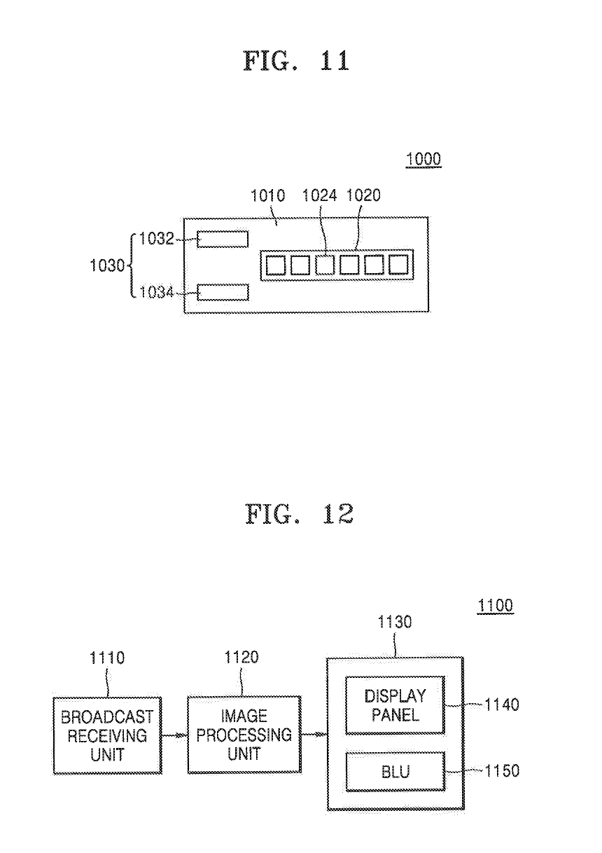

FIG. 11 is a schematic plan view illustrating a dimming system including a semiconductor light-emitting device and/or a light-emitting package, according to an exemplary embodiment of the present inventive concept.

Referring to FIG. 11, a dimming system 1000 may include a light-emitting module 1020 and a power supply unit 1030 disposed on a structure 1010.

The light-emitting module 1020 may include a plurality of light-emitting device packages 1024. The plurality of light-emitting device packages 1024 may include the semiconductor light-emitting devices 100 and 100a, the light-emitting packages 200 and 200a and/or the light-emitting module 700. In addition, the plurality of light-emitting device packages 1024 may include at least one semiconductor light-emitting device, a light-emitting package and/or a light-emitting module modified and changed therefrom.

The power supply unit 1030 may include an interface 1032 via which power is input, and a power controller 1034 which controls power provided to the light-emitting module 1020. The interface 1032 may include a fuse for breaking an overcurrent, and an electromagnetic shielding filter for blocking an electromagnetic interference signal. The power controller 1034 may include a rectification unit and a smoothing unit for converting the alternating current into a direct current when an alternating current is input as power, and a constant voltage controller for conversion into a voltage suitable for the light-emitting module 1020. The power supply unit 1030 may include a feedback circuit device for comparing an emission amount at the plurality of light-emitting device packages 1024 with a previously set amount of light, and a memory device for storing information such as a desired luminance, color rendering, etc.

In an exemplary embodiment of the present inventive concept, the dimming system 1000 may be used as a backlight unit (BLU) for use in a display apparatus such as a liquid crystal display (LCD) apparatus including an image panel, an indoor illumination apparatus such as a lamp, flat panel illumination, etc., or an outdoor illumination apparatus such as a signboard, a signpost, etc. In an exemplary embodiment of the present inventive concept, the dimming system 1000 may be used in an illumination apparatus in various means of transportation, for example, an illumination apparatus for an automobile, a ship, or an aircraft. In addition, the dimming system 1000 may be used in a household appliance such as a TV, a refrigerator, etc., a medical device, or the like.

FIG. 12 is a block diagram of a display apparatus 1100 including a semiconductor light-emitting device and/or a light-emitting package, according to an exemplary embodiment of the present inventive concept.

Referring to FIG. 12, the display apparatus 1100 may include a broadcast receiving unit 1110, an image processing unit 1120, and a display 1130.

The display 1130 may include a display panel 1140 and a BLU 1150. The BLU 1150 may include light sources for generating light and driving devices for driving the light sources.

The broadcast receiving unit 1110, which is an apparatus for selecting a channel of a broadcast which is received wirelessly or via wires in the air or through cables, may set a channel from among a plurality of channels as an input channel, and may receive a broadcast signal of the channel set as the input channel.

The image processing unit 1120 may perform signal processing, such as video decoding, video scaling, frame rate conversion (FRC), etc., on broadcast content output from the broadcast receiving unit 1110.

The display panel 1140 may be configured as an LCD, but is not limited thereto. The display panel 1140 displays broadcast content that is signal-processed in the image processing unit 1120. The BLU 1150 projects light onto the display panel 1140 so that the display panel 1140 may display an image. The BLU 1150 may include the semiconductor light-emitting devices 100 and 100a, the light-emitting packages 200 and 200a and/or the light-emitting module 700, and a semiconductor light-emitting device, a light-emitting package and/or a light-emitting module modified and changed therefrom.

While the present inventive concept has been shown and described with reference to the exemplary embodiments thereof, it will be apparent to those of ordinary skill in the art that various changes in form and detail may be made thereto without departing from the spirit and scope of the present inventive concept as defined by the following claims.

What is claimed is:

1. A light-emitting package comprising:
a light-emitting structure having a first surface and a second surface opposite to the first surface;
an electrode layer disposed on the first surface;
an insulating layer disposed on the light-emitting structure and the electrode layer;
an interconnection conductive layer penetrating the insulating layer and connected to the electrode layer; and
a reflective layer disposed between the insulating layer and the interconnection conductive layer, wherein the reflective layer reflects light generated from the light-emitting structure in a direction toward the second surface.

2. The light-emitting package of claim 1, further comprising an adhesive layer disposed between the insulating layer and the reflective layer.

3. The light-emitting package of claim 1, further comprising a first region where the light-emitting structure is located, and a second region around the first region, wherein
the insulating layer comprises a first portion covering a side surface of the light-emitting structure, and a second portion extending away from the side surface of the light-emitting structure, and
at least a portion of the interconnection conductive layer overlaps the first portion of the insulating layer and the second portion of the insulating layer.

4. The light-emitting package of claim 3, wherein a portion of the reflective layer covers the first portion of the insulating layer and the second portion of the insulating layer.

5. The light-emitting package of claim 4, further comprising an adhesive layer disposed between the first portion of the insulating layer and the reflective layer and between the second portion of the insulating layer and the reflective layer.

6. The light-emitting package of claim 3, wherein the insulating layer is exposed through a side surface of the light-emitting package.

7. The light-emitting package of claim 3, further comprising a resin layer covering the interconnection conductive layer,
wherein, in the second region, the reflective layer is disposed between the insulating layer and the resin layer and between the insulating layer and the interconnection conductive layer.

8. The light-emitting package of claim 3, further comprising a wavelength conversion layer disposed on the second surface of the light-emitting structure and the second portion of the insulating layer.

9. The light-emitting package of claim 8, wherein the wavelength conversion layer directly contacts the second surface and the second portion of the insulating layer.

10. The light-emitting package of claim 1, wherein the electrode layer comprises:
a lower electrode structure contacting the first surface of the light-emitting structure; and
an upper electrode structure covering the lower electrode structure and disposed between the insulating layer and the lower electrode structure, wherein at least a portion of the upper electrode structure faces the first surface of the light-emitting structure and reflects light generated from the light-emitting structure.

11. The light-emitting package of claim 10, wherein the electrode layer further comprises a fixing structure disposed between the lower electrode structure and the upper electrode structure and between the first surface of the light-emitting structure and the upper electrode structure.

12. A light-emitting package comprising:
a first region in which a light-emitting structure having a first surface and a second surface opposite to each other is located;
a second region adjacent to the first region;
an insulating layer covering the first surface and a side surface of the light-emitting structure and extending from the first region to the second region;
an interconnection conductive layer overlapping the insulating layer and extending from the first region to the second region; and
a reflective layer disposed between the insulating layer and the interconnection conductive layer.

13. The light-emitting package of claim 12, further comprising an adhesive layer disposed between the insulating layer and the reflective layer.

14. The light-emitting package of claim 12, further comprising an electrode layer disposed on the first surface of the light-emitting structure,
wherein the electrode layer comprises:
a lower electrode structure disposed on the first surface of the light-emitting structure;
an upper electrode structure covering the lower electrode structure and comprising a material that is different from that of the lower electrode structure; and
a fixing structure disposed between the lower electrode structure and the upper electrode structure and between the first surface of the light-emitting structure and the upper electrode structure.

15. The light-emitting package of claim 12, further comprising a wavelength conversion layer covering the second surface of the light-emitting structure and a portion of the insulating layer in the second region,
wherein a side surface of the wavelength conversion layer, a side surface of the insulating layer, and a side surface of the reflective layer are coplanar.

16. The light-emitting package of claim 12, wherein the reflective layer and the interconnection conductive layer comprise different materials from each other.

17. A light-emitting module comprising:
a module substrate; and
a light-emitting package mounted on the module substrate,
wherein the light-emitting package comprises:
a light-emitting structure having a first surface and a second surface opposite to the first surface, the light emitting structure comprising a first semiconductor layer, an active layer, and a second semiconductor layer;
an electrode layer comprising a first electrode contacting the first semiconductor layer and a second electrode contacting the second semiconductor layer;
an insulating layer covering the first surface and a side surface of the light-emitting structure;
a reflective layer overlapping the insulating layer;
an adhesive layer disposed between the insulating layer and the reflective layer; and
an interconnection conductive layer spaced apart from the insulating layer, and having a first interconnection conductive layer and a second interconnection conductive layer respectively connected to the first electrode and the second electrode.

18. The light-emitting module of claim 17, wherein a portion of the insulating layer and a portion of the interconnection conductive layer cover the side surface of the light-emitting structure and extend from the side surface of the light-emitting structure to an area outside of the light-emitting structure.

19. The light-emitting module of claim 18, wherein the insulating layer, the adhesive layer, and the reflective layer are exposed through a side surface of the light-emitting package.

20. The light-emitting module of claim 17, wherein the first electrode or the second electrode comprises:
a lower electrode structure contacting the first surface of the light-emitting structure;
an upper electrode structure covering the lower electrode structure, wherein at least a portion of the upper electrode structure faces the first surface; and
a transparent conductive oxide disposed between the lower electrode structure and the upper electrode structure and between the first surface and the upper electrode structure.
